(19) United States
(12) Patent Application Publication
(10) Pub. No.: US 2012/0055554 A1
(43) Pub. Date: Mar. 8, 2012

(54) COPPER ZINC TIN CHALCOGENIDE NANOPARTICLES

(75) Inventors: Daniela Rodica Radu, West Grove, PA (US); Jonathan V. Caspar, Wilmington, DE (US); Lynda Kaye Johnson, Wilmington, DE (US); H. David Rosenfeld, Drumore, PA (US); Irina Malajovich, Swarthmore, PA (US); Meijun Lu, Hockessin, DE (US)

(73) Assignee: E.I. Du Pont De Nemours and Company, Wilmington, DE (US)

(21) Appl. No.: 13/320,156

(22) PCT Filed: May 21, 2010
(86) PCT No.: PCT/US10/35734

§ 371 Date: Nov. 11, 2011

Related U.S. Application Data
(60) Provisional application No. 61/180,179, filed on May 21, 2009.
(60) Provisional application No. 61/180,184, filed on May 21, 2009.

(51) Int. Cl. H01L 31/0264; C09D 11/00; B05D 3/02; B05D 7/24; H01B 1/02; B05D 3/00; B82Y 30/00

(52) U.S. Cl. 136/264; 252/519.14; 106/31.92; 427/372.2; 977/773

(57) ABSTRACT

This invention relates to nanoparticles of kesterite (copper zinc tin sulfide) and copper zinc tin selenide nanoparticles, inks and devices thereof, and processes to prepare same. The nano-particles are useful to for the absorber layer as a p-type semiconductor in a thin film solar cell application.

This application claims priority under 35 U.S.C. §119(e) from, and claims the benefit of, the following U.S. Provisional Applications: No. 61/180,179, No. 61/180,181, No. 61/180,184, and No. 61/180,186; each of which was filed on May 21, 2009, and each of which is by this reference incorporated in its entirety as a part hereof for all purposes.

### TECHNICAL FIELD

This invention relates to copper zinc tin chalcogenide nanoparticles, compositions thereof, and their use in thin films and devices. The nanoparticles are a p-type semiconductor useful for the absorber layer in a solar cell.

### BACKGROUND

Solar cells, also termed photovoltaic or PV cells, and solar modules convert sunlight into electricity. These devices utilize the specific electronic properties of semiconductors to convert the visible and near visible light energy of the sun into usable electrical energy. This conversion results from the absorption of radiant energy in the semiconductor materials, which frees some valence electrons, thereby generating electron-hole pairs. The terms “band gap energy”, “optical band gap” and “band gap” as used in the art refer to the energy required to generate electron-hole pairs in a semiconductor material, which in general is the minimum energy needed to excite an electron from the valence band to the conduction band.

Solar cells have been traditionally fabricated using silicon (Si) as a light-absorbing, semiconducting material in a relatively expensive production process. To make solar cells more economically viable, solar cell device architectures have been developed that can inexpensively make use of thin-film, light-absorbing semiconductor materials such as copper-indium-gallium-sulfo-di-selenide, Cu(In, Ga)(S, Se)₂, also termed CIGS. This class of solar cells typically has a p-type absorber layer sandwiched between a back electrode layer and an n-type junction partner layer. The back electrode layer is often Mo, while the junction partner is often CdS. A transparent conductive oxide (TCO) such as but not limited to zinc oxide doped with aluminum is formed on the junction partner layer and is typically used as a transparent electrode. CIS-based solar cells have been demonstrated to have power conversion efficiencies exceeding 19%.

The development of nanocrystalline CIGS and the production of films therefrom have been reported in a number of papers and patent applications. For example, WO 08/021604 describes the production of chalcopyrite nanoparticles by reacting a metal component with an elemental chalcogenide precursor in the presence of an alkylamine solvent with a normal boiling temperature of above about 200° C. and an average particle size of from about 5 nm to about 1000 nm. Reaction temperatures were varied from 265-280° C. WO 99/037832 discloses a method of forming a film of metal chalcogenide semiconductor material on a substrate from a colloidal suspension comprising metal chalogenide nanoparticles and a volatile capping agent. The colloidal suspension is made by reacting a metal salt with a chalcogenide salt to precipitate a metal chalcogenide, recovering the metal chalcogenide, and admixing the metal chalcogenide with a volatile capping agent, while WO 09/051862 discloses semiconductor thin films formed from nonspherical particles, including inks thereof.

Despite the demonstrated potential of CIGS in thin-film solar cells, the toxicity and low abundance of indium and selenium are major impediments to the widespread use and acceptance of CIGS in commercial devices. An alternative for absorber layers of thin film solar cells is copper zinc tin sulfide, Cu₂ZnSnS₄ (CZTS). It has a direct bandgap of about 1.5 eV and an absorption coefficient greater than 10⁴ cm⁻¹. In addition, CZTS does not include any toxic or nonabundant elements. Whereas crystals of CIGS have a chalcopyrite structure, CZTS crystals pack in a kesterite structure that is related to the chalcopyrite structure by doubling along the c-axis.

Currently, the development of solar cells based upon CZTS lags significantly behind CIGS-based solar cells. Although the first CZTS heterojunction PV cell was reported in 1996, the current record efficiency for a CZTS cell is 9.6%. To date, thin films of CZTS have been prepared via sputtering of Cu, SnS, and ZnS precursors, hybrid sputtering, pulsed laser deposition, spray pyrolysis of halides and thiourea complexes, electrodeposition/thermal sulfurization, E-beam Cu/Zn/Sn/thermal sulfurization, sol-gel followed by thermal sulfurization and via printed precursors. A hybrid solution-particle approach to CZTS involving the preparation of a hydrazine-based slurry comprising dissolved Cu—Sn chalcogenides (S or S—Se), Zn-chalcogenide particles, and excess chalcogen has been reported. Hydrazine is a highly reactive and potentially explosive solvent that is described in the Merck Index as a “violent poison”.

A need thus remains for the development of improved CZTS particles, and compositions, films and devices made therefrom.

### SUMMARY

In one embodiment, there is provided in this invention a quaternary nanoparticle that contains copper, zinc, tin, a chalcogen, and a capping agent, wherein the chalcogen is selected from the group consisting of sulfur, selenium and mixtures thereof.

In another embodiment, there is provided in this invention a composition that contains a plurality of quaternary nanoparticles that contains copper, zinc, tin, a chalcogen, and a capping agent, wherein the chalcogen is selected from the group consisting of sulfur, selenium and mixtures thereof.

In a further embodiment, there is provided in this invention an ink that contains an organic solvent, and a composition that contains a plurality of quaternary nanoparticles that contains copper, zinc, tin, a chalcogen, and a capping agent, wherein the chalcogen is selected from the group consisting of sulfur, selenium and mixtures thereof.

In yet another embodiment, there is provided in this invention a film fabricated from a composition that contains a plurality of quaternary nanoparticles that contains copper, zinc, tin, a chalcogen, and a capping agent, wherein the chalcogen is selected from the group consisting of sulfur, selenium and mixtures thereof. In yet another embodiment, there is provided in this invention an electronic device that contains the above described film.

In yet another embodiment, there is provided in this invention a process for preparing a copper-zinc-tin-chalcogenide quaternary nanoparticle, by (a) forming in a solvent a reaction mixture of (i) metal salts and/or complexes of copper, zinc and tin, (ii) one or more chalcogen precursor(s), and (iii) a capping agent, and (b) heating the reaction mixture to form a nanoparticle.

In yet another embodiment, there is provided in this invention a method of forming a film by depositing on a substrate a layer of a composition that contains a plurality of quaternary nanoparticles that contains copper, zinc, tin, a chalcogen, and a capping agent, wherein the chalcogen is selected from the group consisting of sulfur, selenium and mixtures thereof; and drying the deposited layer of composition to remove solvent therefrom.

This invention addresses a need for the development of environmentally sustainable nanocrystalline semiconductors and inks of such semiconductors, based upon elements of high natural abundance and low toxicity. Furthermore, there is a need for thin films and devices based upon such materials. In light of declining supplies of fossil fuels and the growing global energy demands, particularly desirable are nanocrystalline, environmentally sustainable semiconductors useful in the production of thin film absorber layers suitable for use in solar cells. Also particularly desirable are nanocrystalline materials that can be annealed at lower temperatures. During nanoparticle synthesis, moderate reaction temperatures, short reaction times, and minimal steps in the isolation and purification process are desirable to lower cost, conserve energy and develop a commercially feasible process. Particularly desirable is a process of nanoparticle synthesis in which the as-synthesized reaction mixture utilizes solvents and reagents with relatively low toxicity and may serve as the ink or ink precursor, with no isolation or purification steps.

Moreover, nanocrystalline semiconductors, and synthetic routes to such nanoparticles, are of interest because such nano-sized particles possess a number of unique physiochemical properties such as quantum size effects, size-dependent chemical reactivity, optical non-linearity, and efficient photoelectron emission. Films of nanocrystalline semiconductors can serve as precursor films to the absorber layer in thin-film solar cells with significantly lower annealing temperatures than films prepared from larger particles. Beyond the inherent energy savings associated with a reduced thermal budget, the reduced deposition temperature allows the use of lower cost substrates such as soda-lime glass and potentially even polymer-based substrates, while alleviating substrate out diffusion and relieving thermal stress.

### BRIEF DESCRIPTION OF THE DRAWINGS

Various features and/or embodiments of this invention are illustrated in drawings as described below. These features and/or embodiments are representative only, and the selection of these features and/or embodiments for inclusion in the drawings should not be interpreted as an indication that subject matter not included in the drawings is not suitable for practicing the invention, or that subject matter not included in the drawings is excluded from the scope of the appended claims and equivalents thereof.

FIGS. 1-1, 1-2, 1-3 and 1-4 show transmission electron micrographs (“TEM”) of nanoparticles prepared in Example 1.

FIG. 2 shows a TEM of nanoparticles prepared in Example 2.

FIG. 3 shows a perspective view of a stack of layers in a solar cell.

FIG. 4 shows performance data for a film as prepared in Example 15.

### DETAILED DESCRIPTION

This invention involves quaternary nanoparticles that contain copper, zinc, tin and sulfur and/or selenium, and are referred to in certain embodiments by the term “CZTS”, which can be a compound such as Cu₂ZnSnS₄. Examples of other compounds included herein are“CZTSe”, which refers to Cu₂ZnSnSe₄; and “CZTS/Se”, which encompasses all possible combinations of Cu₂ZnSn(S, Se)₄, including Cu₂ZnSnS₄, Cu₂ZnSnSe₄ and Cu₂ZnSnSₓSe₄, where 0≦x≦4. The terms “CZTS”, “CZTSe” and “CZTS/Se” thus further encompass copper zinc tin sulfide/selenide semiconductors with a range of stoichiometries, for example those described by the formla Cu_{1.94}Zn_{0.63}Sn_{1.3}S₄. That is, the stoichiometry of the elements is not limited strictly to a ratio of 2Cu:1Zn:1Sn:4S/Se (i.e. where the molar ratio of copper to zinc to tin to chalcogen is about 2:1:1:4). In other embodiments, the molar ratio of Cu/(Zn+Sn) can be less than 1.0, or the molar ratio of zinc to tin of can be greater than one. In copper-poor CZTS solar cells, for example, the molar ratio of Cu/(Zn+Sn) is less than 1.0 although, for high efficiency devices, a molar ratio of zinc to tin of greater than one is frequently desirable. The compounds may also be doped with small amounts of various dopants selected from the group consisting of binary semiconductors, elemental chalcogens, sodium, and mixtures thereof.

CZTS crystallizes with, and thus has, a kesterite structure, where the term “kesterite” refers to materials belonging to the kesterite and stannite family of minerals. Kesterite is a mineral name referring to crystalline compounds in either the I4- or I4-2m space groups having the nominal formula Cu₂ZnSnS₄. Other metals, such as Fe, often substitute for Zn, however. When a majority of the Zn has been substituted by Fe it is referred to as stannite. Kesterite was once thought to exist only in the I4-form with Cu on positions 2a (0,0,0) and 2c (0,1/2,1/4), and Zn on 2d (1/2,0,1/4), however it has been shown to exhibit disorder in which Zn may occupy Cu sites and vice versa, lower the symmetry to I4-2m. The difference in cation ordering is indistinguishable by x-ray diffraction, owing to the similarity of x-ray scattering factors for Cu and Zn. It can be distinguished by neutron diffraction. Materials produced by this route yield diffraction patterns containing peaks consistent with the kesterite structure and distinct from the monosulfides and oxides. X-ray absorption spectroscopy (XAS) likewise reveals spectral features unique to the kesterite form and distinct from the monosulfides and oxides. In the case of XAS, the fraction of Cu atoms and Zn atoms in the kesterite phase is obtained. This, along with the overall elemental stoichiometry, allows for determination of the ratio of Cu to Zn in the kesterite phase. This is clearly distinguished from a mixture of separate sulfide phases producing the same elemental ratios in aggregate. The kesterite and stannite family of minerals is discussed further in sources such as Hall, S. R. et al, Canadian Minerologist, 16 (1978) 131-137.

In one embodiment of this invention, there is provided a nanoparticle that contains copper, zinc, tin and a chalcogen, wherein the chalcogen is selected from the group consisting of sulfur, selenium and mixtures thereof. As used herein, the term “chalcogen” refers to Group 16 elements, and the terms “metal chalcogenides” or “chalcogenides” refer to semiconductor materials comprised of metals and Group 16 elements. Herein the term “binary-metal chalcogenide” refers to a chalcogenide composition comprising one metal. The term “ternary-metal chalcogenide” refers to a chalcogenide composition comprising two metals. The term “quaternary-metal chalcogenide” refers to a chalcogenide composition comprising three metals. The term “multinary-metal chalcogenide” refers to a chalcogenide composition comprising two or more metals and encompasses ternary and quaternary metal chalcogenide compositions. Metal chalcogenides are useful candidate materials for photovoltaic applications, since many of these compounds have optical band gap values well within the terrestrial solar spectra.

The particle of copper, zinc, tin and a chalcogen that is provided herein is a nanoparticle that has a longest dimension of about 1 nm to about 1000 nm. Herein the terms “nanoparticle”, “nanocrystal” and “nanocrystalline particle” are used interchangeably to refer to particles having a crystalline structure and a variety of shapes including spheres, rods, wires, tubes, flakes, whiskers, rings, disks and triangles, that are characterized by a longest dimension of about 1 nm to about 1000 nm, preferably, about 5 nm to about 500 nm, and most preferably about 10 nm to about 100 nm, where the prefix “nano” refers to a size (as set forth) in the nano range. The longest dimension of a nanoparticle is defined as the measurement of a nanoparticle from end to end along the longest dimension, and this dimension will depend on the shape of the particle. For example, for particles that are, or are substantially, spheroid, the longest dimension will be a diameter of a circle as defined by the particle. For other irregularly-shaped particles (e.g. crystals that may have angular shapes), the longest dimension may be a diagonal or a side such that the longest dimension is the furthest distance between any two points on the surface of the particle. Methods for determining the longest dimension of a nanoparticle are discussed further in sources such as “Nanoparticles: From Theory to Application”, G. Schmid, (Wiley-VCH, Weinheim, 2004); and “Nanoscale Materials in Chemistry”, K. J. Klabunde, (Wiley-Interscience, New York, 2001). In certain particular embodiments of this invention, the nanoparticles provided herein are triangular in shape.

In another embodiment hereof, the nanoparticle of copper, zinc, tin and chalcogen that is provided can incorporate therein a capping agent, which can be a group or ligand that is physically absorbed or adsorbed, or is chemically bonded to the surface of the particle. The capping agent functions as a type of monolayer or coating on the particle and may serve as a dispersing aid. Where a ligand functions as a capping agent, a metal complex is often formed wherein a metal is bonded to a surrounding array of molecules or anions. The atom within a ligand that is directly bonded to the central atom or ion is called the donor atom and often comprises nitrogen, oxygen, phosphorus or sulfur. The ligand donates at least one pair of electrons to the metal atom. Examples of capping agents suitable for use herein include any one or more of the following:
(a) organic molecules that contain functional groups such as nitrogen-, oxygen-, sulfur-, or phosphorus-based functional groups;
(b) a Lewis base; in various embodiments, the Lewis base can be chosen such that it has a boiling temperature at ambient pressure that is greater than or equal to about 150° C., and/or can be selected from the group consisting of: organic amines, phosphine oxides, phosphines, thiols, and mixtures thereof;
(c) an electron pair-donor group, or a group that can be converted into an electron pair-donor group, and that has a boiling point of less than about 150° C. at ambient pressure;
(d) primary, secondary or tertiary amine groups or amide groups, nitrile groups, isonitrile groups, cyanate groups, isocyanate groups, thiocyanate groups, isothiocyanate groups, azide groups, thiogroups, thiolate groups, sulfide groups, sulfinate groups, sulfonate groups, phosphate groups, phosphine groups, phosphite groups, hydroxyl groups, alcoholate groups, phenolate groups, ether groups, carbonyl groups and carboxylate groups;
(e) carboxylic acid, carboxylic acid anhydride, and glycidyl groups; ammonia, methyl amine, ethyl amine, butylamine, tetramethylethylene diamine, acetonitrile, ethyl acetate, butanol, pyridine, ethanethiol, tetrahydrofuran, and diethyl ether;
(f) the solvent in which the nanoparticle is formed, such as oleylamine; and/or
(g) a member of the group consisting of amines, amides, nitriles, isonitriles, cyanates, isocyanates, thiocyanates, isothiocyanates, azides, thiocarbonyls, thiolates, sulfides, sulfinates, sulfonates, phosphates, phosphines, phosphites, hydroxyls, alcoholates, phenolates, ethers, carbonyls, carboxylates, carboxylic acids, carboxylic acid anhydrides, glycidyls, and mixtures thereof.

In yet another embodiment, this invention provides a composition that contains a plurality of nanoparticles as described above. Such a composition can, for example, have particle size distribution such that the average longest dimension of the particles is in the range of about 10 nm to about 100 nm with a standard deviation of about 10 nm or less.

A nanoparticle as provided herein can be made in a reaction mixture in a solvent such as an organic solvent. Suitable organic solvents include Lewis bases and organic solvents capable of forming a Lewis base. The purpose of the solvent is to provide a medium for the reaction and to assist in minimizing or preventing agglomeration of the nanoparticles. Suitable organic solvents that serve as both the solvent and the capping agent include solvents with Lewis basic functionality. A Lewis basic solvent is useful for such purpose as it frequently, but not always, succeeds in providing a coordinating media that covers the surface of nanoparticles and keeps them from agglomerating. Some specific classes of suitable organic solvents include organic amines, phosphine oxides, phosphines and thiols. Preferred solvents are alkyl amines, with the group consisting of dodecylamine, tetradecyl amine, hexadecyl amine, octadecyl amine, oleylamine, and trioctylamine being more preferred, and oleylamine being particularly preferred. Solvents suitable for use herein include those having a boiling temperature at ambient pressure greater than or equal to about 150° C. For example, Lewis basic solvents with a boiling temperature at ambient pressure greater than or equal to about 150° C. are also useful, with the group consisting of organic amines, phosphine oxides, phosphines and thiols with a boiling point temperature at ambient pressure greater than or equal to about 150° C. being more preferred, and alkyl amines with a boiling temperature at ambient pressure greater than or equal to about 150° C. being particularly preferred.

Metal salts and/or complexes of copper, zinc and tin are used as the source of copper, zinc and tin. These may include copper complexes, zinc complexes, and tin complexes of one or more organic ligand(s). Suitable metal salts and/or complexes also comprise salts and complexes of copper(I), copper(II), zinc(II), tin(II) and tin(IV) with organic and/or inorganic counterions and ligands. Metal salts and/or complexes comprising copper(I), copper(II), zinc(II), tin(II) and tin(IV) halides, acetates, and 2,4-pentanedionates are particularly preferred. Suitable chalcogen sources or precursors are elemental sulfur, elemental selenium or a mixture. An advantage of using elemental chalcogen as the chalcogen source is that it facilitates using the reaction mixture itself as an ink or ink precursor without further purification. Copper(I), copper(II), zinc(II), tin(II) and tin(IV) complexes with organic ligands are preferred for applications in which the reaction mixture will be used as the ink or ink precursor. Copper(I), copper(II), zinc(II), tin(II) and tin(IV) complexes of acetates and 2,4-pentanedionates are particularly preferred for this application.

Other suitable copper salts and/or complexes include those selected from the group consisting of: copper(I) halides, copper(I) acetates, copper(I) 2,4-pentanedionates, copper(II) halides, copper(II) acetates, and copper(II) 2,4-pentanedionates; the zinc salts and or complexes are selected from the group consisting of: zinc(II) halides, zinc(II) acetates, and zinc(II) 2,4-pentanedionates; and the tin salts and/or complexes are selected from the group consisting of: tin(II) halides, tin(II) acetates, tin(II) 2,4-pentanedionates, tin(IV) halides, tin(IV) acetates, and tin(IV) 2,4-pentanedionates.

As mentioned above, the term “metal complexes” as used herein refers to compositions wherein a metal is bonded to a surrounding array of molecules or anions, typically called “ligands” or “complexing agents”. The atom within a ligand that is directly bonded to the central atom or ion is called the donor atom and often comprises nitrogen, oxygen, phosphorus, or sulfur. A ligand donates at least one pair of electrons to the metal atom. Herein the term “complexes of one or more organic ligand(s)” refers to metal complexes comprising at least one organic ligand, including metal acetates and metal acetylacetonates, also referred to as “2,4-pentanedionates”. The term “metal salts” refers to compositions wherein metal cations and inorganic anions are joined by ionic bonding. Relevant classes of inorganic anions comprise oxides, sulfides, carbonates, sulfates and halides.

A heating mantle, heating block, or oil/sand bath can be used to heat the flask containing the reaction mixture. Alternatively, the heating may be carried out with microwave radiation. A magnetic stirrer is usually placed inside the flask to keep the reaction mixture well mixed. Optionally, following synthesis, nanoparticles may be separated from non-ligated solvent and reaction by-products via precipitation with one or more nonsolvent or antisolvents. Preferred antisolvents for precipitation of nanoparticles are organic protic solvents or mixtures thereof, with methanol and ethanol being particularly preferred.

In another embodiment of the processes hereof, individual metal salts of copper, zinc and tin are dissolved separately in a solvent such as oleylamine to form solutions. The solutions are mixed to form a mixture, which is kept at about 100° C. To the mixture, a solution of elemental chalcogen, such as sulfur, in solvent is added. The temperature is raised to 230° C. where the reaction color changes from pale brown to black, indicating the formation of nanoparticles. The reaction heating is turned off after 10 minutes, and the system is allowed to cool down for 1 hour. Then the reaction is quenched with an organic polar protic anti-solvent such as ethanol or mixtures of solvents and anti-solvents, and the solution is centrifuged. The solid migrates to the bottom of the tube and is collected by decanting the supernatant. The solid material is re-suspended at desired concentrations in solvents or mixtures of solvents.

In another embodiment of the processes hereof, the reactant components are added consecutively in sequence. That is, individual salts or complexes of copper, zinc and tin are dissolved separately in a solvent to form solutions. Elemental chalcogen is dissolved in a solvent to form a chalcogen solution. The tin solution and the zinc solution are mixed to form a binary solution. The copper solution is mixed with the binary solution to form a tertiary solution. In a subsequent step the tertiary solution is heated to between 160 and 230° C. under argon. The chalcogen solution is mixed with the tertiary solution at a selected temperature from above to form a quaternary solution. Subsequently, the quaternary solution is cooled to form copper zinc tin sulfide nanoparticles. The copper zinc tin sulfide nanoparticles are separated from the solvent by adding a nonsolvent such as an organic solvent. The organic solvent may be a polar, protic organic solvent or a binary mixture of a polar, protic organic solvent and a non-polar or polar aprotic organic solvent. The copper zinc tin sulfide nanoparticles are separated from the organic solvent by centrifugation and decanting the supernatant.

In another embodiment of the processes hereof, individual metal salts and/or complexes of copper, zinc and tin can be separately added in sequence to a mixture of a solvent and a capping agent to form a reaction mixture, followed by the addition to the reaction mixture of a chalogen precursor. Where a solvent and capping agent are present together in a mixture, the capping agent will typically be selected to a Lewis base, and the solvent will typically be selected to either not be a Lewis base, or to be a Lewis base that binds less strongly to the nanoparticle than the capping agent.

In this invention, it is advantageous to obtain nanoparticle formation at lower than typical temperatures, with temperatures of about 130 to about 300° C. being preferred, about 160 to about 230° C. being more preferred, and about 160 to about 200° C. being most preferred. At about 160 to about 200° C., the processes described herein frequently gives nanoparticles having a longest dimension in the size range of about 10 nm to about 100 nm. These low temperatures provide the advantages of carrying out the procedures at atmospheric or near atmospheric pressure, and of using lower-boiling solvents and capping agents. This will result in fewer carbon-based impurities in annealed films. The more preferred temperatures of about 160 to about 230° C. are lower than temperatures typically reported for production of metal chalcogenide nanoparticles, thus also resulting in energy savings.

Preventing oxygen and/or water from being present in the reaction medium during the synthesis of the chalcogenide nanoparticles, particularly due to the possible formation of metal oxides, is desirable. Special techniques and equipment are available to achieve an oxygen-free atmosphere. As such, the reactant(s) can be prepared in solution(s) in an oxygen-free atmosphere or inside a glove box, for instance, by using a Schlenk line or vacuum line connected to a condenser and round bottom flask. If the introduction of oxygen into the system is unavoidable, however, for example during the addition of solvents or precursor solution to the reaction flask, it may be necessary to degas and/or purge the system with inert gas (e.g. N₂, Ar, or He) to remove the oxygen before proceeding to further steps. Although it may be useful to conduct the reactions herein under oxygen-free atmospheric conditions, such an oxygen-free environment is not required herein and should not be viewed as limiting the scope of the present teachings, as we report herein the formation of CZTS nanoparticles under conditions that limited, but did not necessarily exclude, the presence of oxygen and water.

The processes described herein are characterized by a desirable simplicity of the synthesis process. More particularly, the disclosed reaction is very fast, such that the crystalline CZTS nanoparticles are formed within a few minutes after the constituting precursors are added. In addition, the synthesis of the nanoparticles is performed at a moderate temperature near atmospheric pressure. The synthesis is tolerant of the presence of oxygen. That is, in a number of cases, nanoparticles were formed under an atmosphere of argon, but the precursor solutions were prepared in air and not degassed. Furthermore, the precursors used for the synthesis of the chalcogenide nanoparticles are commonly available, of low toxicity, and are easy to handle. Lastly, the equipment needed for the synthesis methods is commonly available as, for example, special equipment is not needed to achieve high temperatures and pressures.

In yet another embodiment of this invention, the nanoparticles produced by the processes described herein are highly monodispersed.

The processes described herein can be used to synthesize quaternary metal chalcogenide CZTS nanoparticles. The CZTS nanoparticles prepared herein include crystalline particles having narrow size distributions that form stable dispersions within non-polar solvents. Particles as made by the processes hereof were characterized via XRD, TEM, ICP-MS, EDAX, DLS, and AFM. DLS revealed a very narrow size distribution within each category (such as 10±10 nm and 50±10 nm). XRD confirmed the presence of the kesterite structure. ICP and EDAX indicated that the consecutive addition of reactants and the use of chalcogen as a precursor gives more accurate CZTS/Se stoichiometry versus reaction conditions utilizing simultaneous addition or other sources of chalcogen such as thiourea.

The processes described herein can be used to prepare a composition comprising a quaternary nanoparticle characterized by a kesterite structure and an average longest dimension of about 1 nm to about 1000 nm, or a composition comprising a quaternary nanoparticle that is comprised of copper, tin, zinc and one or more chalcogen(s) and that is characterized by an average longest dimension of about 1 nm to about 1000 nm.

The processes described herein can be used to prepare a nanoparticle that contains copper, zinc, tin, a chalcogen and a capping agent, wherein the chalcogen is selected from the group consisting of sulfur, selenium and mixtures thereof, and the nanoparticle has a longest dimension of about 1 nm to about 1000 nm. Other embodiments of the processes of this invention are characterized by the ability to prepare nanoparticles having one or more of the following features:

a kesterite structure;

a molar ratio of copper to zinc to tin to chalcogen that is about 2:1:1:4;

a molar ratio of copper to zinc plus tin that is less than one;

a molar ratio of zinc to tin is greater than one;

the longest dimension is about 10 nm to about 100 nm;

a dopant, such as sodium, is present;

a capping agent comprises a Lewis base;

a capping agent comprises a Lewis base wherein the boiling temperature of the Lewis base at ambient pressure is greater than or equal to about 150° C., and the Lewis base is selected from the group consisting of: organic amines, phosphine oxides, phosphines, thiols, and mixtures thereof;

a capping agent comprises oleylamine;

a capping agent has a boiling point of less than about 150° C. at ambient pressure and comprises at least one electron pair-donor group or group which can be converted into an electron pair-donor group; and/or

a capping agent is selected from the group consisting of: amines, amides, nitriles, isonitriles, cyanates, isocyanates, thiocyanates, isothiocyanates, azides, thiocarbonyls, thiolates, sulfides, sulfinates, sulfonates, phosphates, phosphines, phosphites, hydroxyls, alcoholates, phenolates, ethers, carbonyls, carboxylates, carboxylic acids, carboxylic acid anhydrides, glycidyls, and mixtures thereof.

The processes described herein can also be used to prepare a composition that contains a plurality of nanoparticles as described above, and such a composition of nanoparticles can have an average longest dimension of about 10 nm to about 100 nm with a standard deviation of about 10 nm or less.

In another embodiment, this invention further provides inks that contain CZTS nanoparticles (as described above and/or as prepared by the processes described above) and one or more organic solvent(s). In various embodiments, the reaction mixture of the starting metal components and solvent can itself be used as an ink without further purification. Optionally, following precipitation from a reaction mixture, nanoparticles may be re-suspended at the desired concentration in a solvent or mixture of solvents to give an ink Preferred organic solvents comprise aromatics, alkanes, nitriles, ethers, ketones, esters and organic halides or mixtures thereof with toluene, p-xylene, hexane, heptane, chloroform, methylene chloride and acetonitrile being particularly preferred. Preferred concentrations of nanoparticles in the solvents are about 1 wt % to about 70 wt % with about 5 wt % to about 50 wt % being more preferred, and about 10 wt % to about 40 wt % being most preferred.

In addition to CZTS nanoparticles and an organic solvent, the ink may optionally further comprise one or more chemicals including without limitation dispersants, surfactants, polymers, binders, cross-linking agents, emulsifiers, anti-foaming agents, dryers, fillers, extenders, thickening agents, film conditioners, anti-oxidants, flow agents, leveling agents, and corrosion inhibitors, and mixtures thereof. Preferred additives are oligomeric or polymeric binder(s) and mixtures thereof and/or a surfactant. Preferably, oligomeric or polymeric binders are present in an amount of about 20 wt % or less, more preferably about 10 wt % or less, even more preferably about 5 wt % or less with about 2 wt % or less being most preferred. These oligomeric or polymeric binders may have a variety of architectures including linear, branched, comb/brush, star, hyperbranched and/or dendritic architectures.

A preferred class of oligomeric or polymeric binders comprises decomposable binders with decomposition temperatures of preferably about 250° C. or less, more preferably about 200° C. or less. Preferred classes of decomposable oligomeric or polymeric binders comprise homo- and co-polymers of polyethers, polylactides, polycarbonates, poly[3-hydroxybutyric acid], and polymethacrylate. More preferred decomposable oligomeric or polymeric binders comprise poly(methacrylic) copolymers, poly(methacrylic acid), poly(ethylene glycol), poly(lactic acid), poly[3-hydroxybutryic acid], poly(DL-lactide/glycolide), poly(propylene carbonate) and poly(ethylene carbonate). Especially preferred decomposable binders comprise the group consisting of Elvacite® 2028 binder and Elvacite® 2008 binder (Lucite International, Inc.). Preferably, decomposable oligomeric or polymeric binders are present in an amount of about 50 wt % or less, more preferably about 20 wt % or less, even more preferably about 10 wt % or less with about 5 wt % or less being most preferred.

If present in the nanoparticle ink, a surfactant is preferably present in amounts of about 10 wt % or less, more preferably about 5 wt % or less, and even more preferably about 3 wt % or less, with 1 wt % or less being most preferred. Numerous surfactants are available that are suitable for this purpose. Selection can be based upon the observed coating and dispersion quality and/or desired adhesion to the substrate. In certain embodiments, the surfactants comprise siloxy-, fluoryl-, alkyl-and alkynyl-substituted surfactants. These include, for example, Byk® surfactants (Byk Chemie), Zonyl® surfactants (DuPont), Triton® surfactants (Dow), Surfynol® surfactants (Air Products) and Dynol® surfactants (Air Products). A preferred class of surfactants comprises cleavable or decomposable surfactants and surfactants with a boiling point below about 250° C., preferably below about 200° C., and more preferably below about 150° C. A preferred low boiling surfactant is Surfynol® 61 surfactant from Air Products. Cleavable surfactants are further discussed in sources such as “Cleavable Surfactants”, Hellberg et al, Journal of Surfactants and Detergents, 3 (2000) 81-91; and “Cleavable Surfactants”, Tehrani-Bagha et al, Current Opinion in Colloid and Interface Science, 12 (2007) 81-91.

The ink may optionally further comprise other semiconductors and dopants. Preferred dopants are binary semiconductors, elemental chalcogens, and sodium. If present in the ink, dopants are preferably present at about 10 wt % or less, more preferably about 5 wt % or less, and most preferably at about 2 wt % or less.

In one particular embodiment, this invention thus provides an ink that contains nanoparticles characterized by a kesterite structure and/or an average longest dimension of about 1 nm to about 1000 nm. In another embodiment, this invention provides an ink comprising nanoparticles that are comprised of copper, tin, zinc, one or more chalcogen(s) and a capping agent. The nanoparticles comprised of copper, tin, zinc, one or more chalcogen(s) and a capping agent may also be characterized by a kesterite structure and/or an average longest dimension of about 1 nm to about 1000 nm.

In other embodiments, this invention also provides an ink that contains one or more organic solvents together with a composition of a plurality of nanoparticles wherein a nanoparticle in the composition contains copper, zinc, tin, a chalcogen, and a capping agent, wherein the chalcogen is selected from the group consisting of: sulfur, selenium. In yet other embodiments, the composition of nanoparticles in an ink, or a nanoparticle in the composition, is characterized by one or more of the following features:
a nanoparticle in the composition has a kesterite structure;
a nanoparticle in the composition has a molar ratio of copper to zinc to tin to chalcogen of about 2:1:1:4;
a nanoparticle in the composition has a molar ratio of copper to zinc plus tin of less than one;
a nanoparticle in the composition has a molar ratio of zinc to tin of greater than one;
a nanoparticle has a longest dimension of about 1 nm to about 1000 nm;
a nanoparticle in the composition contains a capping agent having an electron pair-donor group, or group which can be converted into an electron pair-donor group, selected from the group consisting of: amines, phosphine oxides, phosphines, thiols, amides, nitriles, isonitriles, cyanates, isocyanates, thiocyanates, isothiocyanates, azides, thiocarbonyls, thiolates, sulfides, sulfinates, sulfonates, phosphates, phosphites, hydroxyls, alcoholates, phenolates, ethers, carbonyls, carboxylates, and mixtures thereof;
a nanoparticle in the composition contains a capping agent that is oleylamine;
the composition has a particle size distribution characterized by an average longest particle dimension of about 10 nm to about 100 nm;
the concentration of nanoparticles in the ink is between about 1 wt % to about 70 wt %, as based upon the total weight of the ink;
the organic solvent in the ink is selected from the group consisting of aromatics, alkanes, nitriles, ethers, ketones, esters, organic halides and mixtures thereof;
the ink also contains constituents selected from the group consisting of dispersants, surfactants, polymers, binders, crosslinking agents, emulsifiers, anti-foaming agents, driers, fillers, extenders, thickening agents, film conditioners, anti-oxidants, flow agents, leveling agents, corrosion inhibitors and mixtures thereof;
the ink contains one or more binders or surfactants selected from the group consisting of decomposable binders; decomposable surfactants; cleavable surfactants; surfactants with a boiling point less than about 250° C.; and mixtures thereof;
the ink contains one or more decomposable binders selected from the group consisting of homo- and co-polymers of polyethers; homo- and co-polymers of polylactides; homo- and co-polymers of polycarbonates; homo- and co-polymers of poly[3-hydroxybutyric acid]; homo- and co-polymers of polymethacrylates; and mixtures thereof; and/or
the ink also contains a dopant selected from the group consisting of binary semiconductors, elemental chalcogens, sodium, and mixtures thereof.

A composition or ink of nanoparticles, as described above, can be formed into a film on a substrate, and such a film may have one or more layers where some or all of the layers are formed from an ink or composition hereof. The substrate, which forms a base on which the layer(s) of film are deposited or disposed, may be flexible or rigid. The substrate may, for example, be prepared from aluminum foil or a polymer, which is then used as a flexible substrate in a roll-to-roll manner (either continuous or segmented) using a commercially available web coating system. A rigid substrate may be comprised of at least one material selected from the group consisting of glass, solar glass, low-iron glass, green glass, soda-lime glass, steel, stainless steel, aluminum, polymer, ceramic, metal plates, metallized ceramic plates, metallized polymer plates, metallized glass plates, and/or any single or multiple combination of the aforementioned.

A film of a composition or ink hereof can be formed on a substrate by any of a variety of solution-based coating techniques including but not limited to wet coating, spray coating, spin coating, doctor blade coating, contact printing, top feed reverse printing, bottom feed reverse printing, nozzle feed reverse printing, gravure printing, microgravure printing, reverse microgravure printing, comma direct printing, roller coating, slot die coating, meyerbar coating, lip direct coating, dual lip direct coating, capillary coating, ink-jet printing, jet deposition, spray deposition, and the like. Other coating techniques useful for film formation include flexographic printing, offset printing, screen printing, and heat transfer printing.

The nanoparticles provided by this invention have semiconductor properties, and unlike conventional semiconductor materials, the nanoparticles hereof tend to interact and agglomerate in a colloidal suspension. The incorporation of a capping agent into the nanoparticles is useful to help stabilize the colloidal suspension and prevent its decomposition. The presence of the capping agent will help prevent interaction and agglomeration of the nanoparticles, thereby maintaining a uniform distribution of the colloidal substance (e.g. metal chalcogenide nanoparticles), the disperse phase, throughout the dispersion medium. Unfortunately, when a nonvolatile capping agent is used, and when a composition or ink of the nanoparticles is formed into a film, the nonvolatile capping agent tends to decompose rather than volatilize, thereby introducing substantial impurities (e.g. carbon) into the film. Although such impurities are not necessarily fatal to film performance, they degrade its electronic properties. In contrast to nonvolatile capping agents, volatile capping agents are typically driven off during deposition of an ink to form a film, instead of breaking down and introducing impurities into the film.

An advantage of this invention is that use of the moderate reaction temperatures, as described above, enables the incorporation of relatively low-boiling capping agents that are not so volatile that they are not retained during the reaction to form the nanoparticles, but that are volatile enough to driven off during film formation. Whichever capping agent is selected for use during nanoparticle formation, however, it may be exchanged for a capping agent having greater volatility in a further process step. For example, a high boiling, nonvolatile capping agent as incorporated during nanoparticle synthesis may be exchanged for a volatile capping agent, such as a volatile coordinating Lewis base, following the synthesis of the nanoparticles. Thus, in one embodiment, a wet nanoparticle pellet stabilized by a nonvolatile capping agent as incorporated during synthesis is suspended in a volatile capping agent to produce a colloidal suspension in which exchange of capping agents has occurred. When the colloidal suspension is then deposited on a substrate, it forms a substantially carbon-free precursor film as the volatile capping agent that had displaced the nonvolatile capping agent is liberated from the suspension during film formation.

In yet another embodiment, an exchange of capping agents can be effected following film formation. An unannealed film can be soaked in a bath in a volatile capping agent, which then exchanges with the nonvolatile capping agent that is incorporated into the as-synthesized nanoparticles. The nonvolatile capping agent is then removed along with the excess volatile capping agent when the film is removed from the bath. Advantages of this method include film densification along with lower levels of carbon-based impurities in the film, particularly if and when it is later annealed. Another advantage of this method is that it is relatively insensitive to the presence of water, which may cause destabilization of the colloidal suspension, agglomeration, and colloid decomposition.

In yet another embodiment, a reaction mixture of nanoparticles that contain a first capping agent can be contacted with a second capping agent that has greater volatility than the first capping agent to exchange in the nanoparticle the second capping agent for the first capping agent; or a nanoparticle that contains a first capping agent can be recovered from a reaction mixture followed by contacting the nanoparticle with a second capping agent that has greater volatility than the first capping agent to exchange in the nanoparticle the second capping agent for the first capping agent. In yet another embodiment, a film that contains a first capping agent can be contacted with a second capping agent that has greater volatility than the first capping agent to exchange in the nanoparticles of the film the second capping agent for the first capping agent. In either of the above embodiments, the second capping agent can have a boiling point of less than about 200° C. at ambient pressure.

A capping agent is considered volatile in the context of this invention if it is sufficiently volatile that, instead of decomposing and introducing impurities when a compositin or ink of nanoparticles is formed into a film, it evolves during film deposition. Capping agents having volatility suitable for use herein include those having a boiling point less than about 200° C. at ambient pressure, preferably less than about 150° C. at ambient pressure, more preferably less than about 120° C. at ambient pressure, and most preferably less than about 100° C. at ambient pressure, where each of those ranges is bounded on the lower end by a nonzero value. Other volatile capping agents suitable for use herein include compounds that contain at least one electron pair-donor group or a group which can be converted into such an electron pair-donor group. The electron pair-donor group can be electrically neutral or negative, and usually contains atoms such and 0, N, P or S. Electron pair-donor groups include without limitation primary, secondary or tertiary amine groups or amide groups, nitrile groups, isonitrile groups, cyanate groups, isocyanate groups, thiocyanate groups, isothiocyanate groups, azide groups, thiogroups, thiolate groups, sulfide groups, sulfinate groups, sulfonate groups, phosphate groups, phosphine groups, phosphite groups, hydroxyl groups, alcoholate groups, phenolate groups, ether groups, carbonyl groups and carboxylate groups. Groups that can be converted into an electron pair donor groups include, for example, carboxylic acid, carboxylic acid anhydride, and glycidyl groups. Specific examples of suitable volatile capping agents include without limitation ammonia, methyl amine, ethyl amine, butylamine, tetramethylethylene diamine, acetonitrile, ethyl acetate, butanol, pyridine, ethanethiol, tetrahydrofuran, and diethyl ether. Preferably, the volatile capping agent is acetonitrile, butylamine, tetramethylethylene diamine, or pyridine.

Although solvent and possibly dispersant are typically removed from a composition or ink hereof by the drying that occurs during film formation, a film as formed herein may be annealed by heating. Heating a film as formed herein typically provides a solid layer at temperatures much lower than a corresponding layer of microparticles, which may be caused in part by the greater surface area contact between particles. In any event, suitable temperatures at which to anneal a film as formed herein include those between about 100° C. to about 1000° C., more preferably between about 200° C. and about 600° C., and even more preferably between about 375° C. and about 525° C., this latter range being a safe temperature range for processing on aluminum foil or high-melting-temperature polymer substrates. A film to be annealed may be heated and/or accelerated via thermal processing techniques using at least one of the following processes: pulsed thermal processing, exposure to laser beams, or heating via IR lamps, and/or similar or related processes. Other devices suitable for rapid thermal processing also include pulsed lasers used in adiabatic mode for annealing, continuous wave lasers (10-30 W typically), pulsed electron beam devices, scanning electron beam systems and other beam systems, graphite plate heaters, lamp systems, and scanned hydrogen flame systems. A non-directed, low density system may also be used. Alternatively, other heating processes suitable for use herein include the pulsed heating processes described in U.S. Pat. Nos. 4,350,537 and 4,356,384; and the pulsed electron beam processing and rapid thermal processing as described in U.S. Pat. Nos. 3,950,187, 4,082,958, and 4,729,962 (each of the above mentioned patents being by this reference incorporated as a part hereof for all purposes). The methods of heating described above may be applied singly, or in single or multiple combinations with each other, and with the above or other similar processing techniques.

The annealing temperature can be modulated to oscillate within a temperature range without being maintained at a particular plateau temperature. This technique (referred to herein as rapid thermal annealing, or RTA) is particularly suitable for forming photovoltaic active layers (sometimes called “absorber” layers) on metal foil substrates, such as but not limited to aluminum foil. Details of this technique are described in U.S. patent application Ser. No. 10/943,685, which is by this reference incorporated herein for all purposes.

The annealed film may have increased density and/or reduced thickness, versus that of the wet precursor layer, since the carrier liquid and other materials have been removed during processing. In one embodiment, the film may have a thickness in the range of about 0.5 microns to about 2.5 microns. In other embodiments, the thickness of the film may be between about 1.5 microns and about 2.25 microns. The processing of the deposited layer of composition or ink will fuse the nanoparticles together and in most instances, remove void space and thus reduce the thickness of the resulting dense film.

Sodium can be incorporated into a composition or ink of CZTS nanoparticles, as provided herein, to improve the qualities of a film formed therefrom. In a first method, in a multilayer film as formed on a substrate, one or more layers of a sodium containing material may be formed above and/or below a layer as formed from the nanoparticles hereof. The formation of the sodium-containing layer may occur by solution coating and/or other techniques including without limitation sputtering, evaporation, CBD, electroplating, sol-gel based coatings, spray coating, CVD, PVD, ALD, and the like. Optionally, in a second method, sodium may also be introduced into the stack of layers in the film by sodium doping the CZTS nanoparticles in the film formed therefrom. Optionally, in a third method, sodium may be incorporated into the ink of nanoparticles itself. For example, the ink may include a sodium compound with an organic or inorganic counter-ion (such as sodium sulfide), where the sodium compound that is added into the ink (as a separate compound) might be present as particles or dissolved. The sodium thus may be present in either or both of the “aggregate” form of the sodium compounds (e.g. dispersed particles), and the “molecularly dissolved” form.

The three abovementioned methods are not mutually exclusive, and each may be applied singly or in any single or multiple combinations with the other(s) to provide a desired amount of sodium to a stack containing a CZTS film. Additionally, sodium and/or a sodium-containing compound may be added to the substrate (e.g. into a molybdenum target). The source of the sodium is not limited, and can include one or more of the following: any deprotonated alcohol where the proton is replaced by sodium, any deprotonated organic or inorganic acid where the proton is replaced by sodium, sodium hydroxide, sodium acetate, and the sodium salts of the following acids: butanoic acid, hexanoic acid, octoanoic acid, decanoic acid, dedecanoic acid, tetradecanoic acid, hexadecanoic acid, and the like. Other sources include sodium halides such as sodium fluoride; and other alkali metals such as K, Rb or Cs may also be used as dopants with similar effect.

Additionally, the sodium material may be combined with other elements that can provide a bandgap widening effect such as Al, Ge and Si. The use of one or more of these elements, in addition to sodium, may further improve the quality of the absorber layer. The use of a sodium compound such as Na₂S, or the like, provides both Na and S to the film, and could be driven in with an anneal such as provided by an RTA step to give a layer with a bandgap different from the bandgap of an unmodified CZTS layer or film.

In yet another embodiment of this invention, a CZTS film can be formed on a substrate that includes a source of extra chalcogen, e.g. in the form of a powder containing chalcogen particles or binary chalcogenide particles. The extra source of chalcogen may be provided as a discrete layer containing extra source of chalcogen, or the extra source of chalcogen can be incorporated in the CZTS composition or ink from which a single layer is printed onto the substrate. The chalcogen particles may be micron- or submicron-sized non-oxygen chalcogen (e.g. Se, S) particles, and may have a longest dimension that is a few hundred nanometers or less to a few microns in size. The chalcogenide particles may be micron- or submicron-sized, and include group IB-binary chalcogenide nanoparticles such as (CuS,Se) and/or group IIA non-oxide chalcogenide nanoparticles such as Zn(Se, S) and/or group IVA binary chalcogenide nanoparticles such as Sn(Se, S)₂. Other suitable chalcogen particles or binary chalogenide particles include those selected from the group consisting of: non-oxygen chalcogen particles, group IB-binary chalcogenide nanoparticles, group IIA non-oxide chalcogenide nanoparticles, Se particles, S particles, CuS particles, CuSe particles, ZnSe particles, ZnS particles, SnSe₂ particles, SnS₂ particles, and mixtures thereof.

To add the source of extra chalcogen, a mixture of the quaternary chalcogenide nanoparticles hereof, and the extra chalcogen particles, is placed on a substrate and heated to a temperature sufficient to melt the extra chalcogen particles to form a liquid chalcogen. The liquid chalcogen and the quaternary nanoparticles are heated to a temperature sufficient to react the liquid chalcogen with the nanoparticles to correct any chalcogen deficiency in the resulting film and to densify the layer. The film is then cooled down.

In some embodiments, a layer of chalcogen particles or binary chalcogenide particles may be formed below the CZTS film. This position of the layer still allows the chalcogen particles to provide a sufficient surplus of chalcogen or other lacking elements to the CZTS layer, and thus to fully react and correct the stochiometry of the quaternary particles hereof. Additionally, since the chalcogen released from the underlying layer may be rising through the CZTS film, this position of the layer may be beneficial to generate greater intermixing between elements. The thickness of the chalcogen rich layer may be in the range of about 0.4 to 0.5 microns. In still another embodiment, the thickness of the chalcogen rich layer is about 500 to 50 nm. In still other embodiments hereof, multiple layers of material may be printed and reacted with chalcogen to differing extents before deposition of the next layer, and in this manner a graded compositional content can be provided across the group of layers making up a multi-layer film.

The binary chalcogenide particles may be obtained starting from a binary chalcogenide feedstock material, e.g. micron size particles or larger. The binary chalcogenide feedstock may be ball milled to produce particles of the desired size. Binary alloy chalcogenide particles may alternatively be formed by pyrometallurgy or by melting elemental components and spraying the melt to form droplets that solidify into nanoparticles.

The chalcogen particles may be larger than the binary chalcogenide nanoparticles and the quaternary chalcogenide nanoparticles since chalcogen particles melt before the binary and quaternary nanoparticles and provide good contact with the material. Preferably the chalcogen particles are smaller than the thickness of the chalcogenide film that is to be formed. The chalcogen particles (e.g. Se or S) may be formed in several different ways. For example, Se or S particles may be formed starting with a commercially available fine mesh powder (e.g. 200 mesh/75 micron) and ball milling the powder to a desirable size. Se or S particles may alternatively be formed using an evaporation-condensation method. Alternatively, Se or S feedstock may be melted and sprayed (“atomization”) to form droplets that solidify into nanoparticles.

Chalcogen particles may also be formed using a solution-based technique such as the “Top-Down” method as described by Wang and Xia in Nano Letters, 2004 Vol. 4, No. 10, 2047-2050 (“Bottom-Up and Top-Down Approaches to Synthesis of Monodispersed Spherical Colloids of Low Melting-Point Metals”). This technique allows processing of elements with melting points below 400° C. as monodispersed spherical colloids, with diameter controllable from 100 nm to 600 nm, and in copious quantities. For this technique, chalcogen (Se or S) powder is directly added to boiling organic solvent, such as di(ethylene glycol) and melted to produce big droplets. After the reaction mixture has been vigorously stirred and thus emulsified for 20 min, uniform spherical colloids of metal are obtained as the hot mixture is poured into a cold organic solvent bath (e.g. ethanol) to solidify the chalcogen (Se or Se) droplets.

In yet another embodiment hereof, an electronic device can be fabricated from a film comprises multiple layers; and a first layer can contain a plurality of nanoparticles as described above, and a second layer can contain a binary semiconductor, a chalcogen source, a sodium-containing material, or a mixtures thereof. In such a device, the first layer can be adjacent to the second layer.

A film fabricated on a substrate as described above can be incorporated into an electronic device to serve, for example, as an absorber layer in a photovoltaic device, module, or solar panel. The typical solar cell includes a transparent substrate (such as soda-lime glass), a back contact layer (e.g.

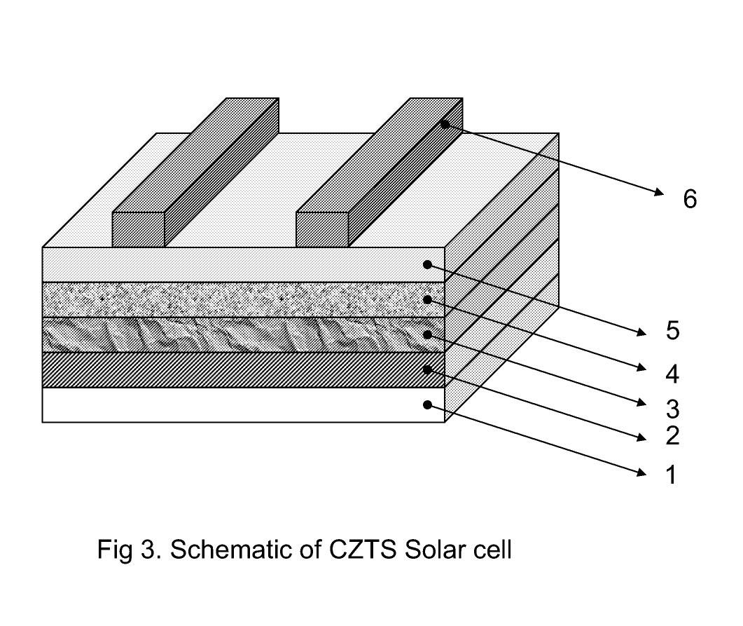

molybdenum), an absorber layer (also referred to as the first semiconductor layer), a buffer layer (e.g. CdS; also referred to as the second semiconductor layer), and a top electrical contact. The solar cell may also include an electrical contact or electrode pad on the top contact layer, and an antireflective (AR) coating on the front surface of the substrate to enhance the initial transmission of light into the semiconductor material. FIG. 3 illustrates the above features in the stack shown therein, which contains the following elements: transparent substrate 1; back contact layer 2; absorber layer 3 (which is formed from the p-type CZTS/Se nanoparticles hereof); buffer layer 4; top contact layer 5 [which can be, for example, a transparent conducting oxide (“TCO”) such as zinc oxide doped with aluminum]; and the electrical contact or electrode pad on the top contact layer 6.

The substrate may be made, for example, of a metal foil, such as titanium, aluminum, stainless steel, molybdenum, or a plastic or polymer, such as polyimides (PI), polyamides, polyetheretherketone (PEEK), polyethersulfone (PES), polyetherimide (PEI), polyethylene naphthalate (PEN), polyester (PET), or a metallized plastic. The base electrode may be made of an electrically conductive material such as a layer of Al foil, e.g. about 10 microns to about 100 microns thick. An optional interfacial layer may facilitate bonding of the electrode to the substrate. The adhesion can be comprised of a variety of materials, including without limitation chromium, vanadium, tungsten, and glass, or compounds such as nitrides, oxides, and/or carbides. The CZTS absorber layer may be about 0.5 micron to about 5 microns thick after annealing, and more preferably from about 0.5 microns to about 2 microns thick after annealing.

The n-type semiconductor thin film (sometimes referred to as a junction partner layer) may include, for example, inorganic materials such as cadmium sulfide (CdS), zinc sulfide (ZnS), zinc hydroxide, zinc selenide (ZnSe), n-type organic materials, or some combination of two or more of these or similar materials, or organic materials such as n-type polymers and/or small molecules. Layers of these materials may be deposited, for example, by chemical bath deposition (CBD) and/or chemical surface deposition (and/or related methods), to a thickness ranging from about 2 nm to about 1000 nm, more preferably from about 5 nm to about 500 nm, and most preferably from about 10 nm to about 300 nm. This may also configured for use in a continuous roll-to-roll and/or segmented roll-to-roll and/or a batch mode system.

The transparent electrode may include a transparent conductive oxide layer such as zinc oxide (ZnO), aluminum doped zinc oxide (ZnO:Al), iindium tin oxide (ITO), or cadmium stannate, any of which can be deposited using any of a variety of means including but not limited to sputtering, evaporation, CBD, electroplating, CVD, PVD, ALD, and the like.

Alternatively, the transparent electrode may include a transparent conductive polymeric layer, e.g. a transparent layer of doped PEDOT (poly-3,4-ethylenedioxythiophene), which can be deposited using spin, dip, or spray coating, and the like. PSS:PEDOT is a doped conducting polymer based on a heterocyclic thiophene ring bridged by a diether. A water dispersion of PEDOT doped with poly(styrenesulfonate) (PSS) is available from H. C. Starck of Newton, Mass. under the trade name of Baytron® P. The transparent electrode may further include a layer of metal (e.g., Ni, Al or Ag) fingers to reduce the overall sheet resistance. Alternatively, the transparent conductor layer may comprise a carbon nanotube-based transparent conductor.

The operation and effects of certain embodiments of the inventions hereof may be more fully appreciated from a series of examples as described below. The embodiments on which these examples are based are representative only, and the selection of those embodiments to illustrate the invention does not indicate that materials, components, reactants, configurations, designs, conditions, specifications, steps, techniques not described in the examples are not suitable for use herein, or that subject matter not described in the examples is excluded from the scope of the appended claims and equivalents thereof.

### EXAMPLES

The following is a list of abbreviations and trade names used above and in the examples:

| Abbreviation | Description |
|---|---|
| XRD | X-Ray Diffraction |
| TEM | Transmission Electron Microscopy |
| ICP-MS | Inductively Coupled Plasma Mass Spectrometry |
| AFM | Atomic Force Microscopy |
| DLS | Dynamic Light Scattering |
| CIGS | Copper-Indium-Gallium-Sulfo-di-selenide |
| CZTS | Copper Zinc Tin Sulfide (Cu₂ZnSnS₄) |
| CZTSe | Copper Zinc Tin Selenide Cu₂ZnSnSe₄) |
| CZTS/Se | All possible combinations of CZTS and CZTSe |
| EDX | Energy-Dispersive X-ray Spectroscopy |
| Deg | Degree |
| Oleylamine | Cis-1-Amino-9-octadecene |
| | CH₃(CH₂)₇CH═CH(CH₂)₇CH₂NH₂ |
| FW | Formula Weight |
| Ex | Example |
| Elvacite 2028 | Methacrylate Copolymer with Tg of 45° C. and MW of |
| | 59,000; Lucite International, Inc. |
| Elvacite 2008 | Methyl Methacrylate Copolymer with Tg of 105° C. and |
| | MW of 37,000; Lucite International, Inc. |
| RTA | Rapid Thermal Anneal |
| TCO | Transparent Conducting Oxide |

### Materials

Cuprous chloride, Cu(I)Cl 99.99%, zinc chloride, ZnCl₂ 99.99%; tin chloride, SnCl₂ 99.99%, elemental sulfur, elemental selenium, thiourea, toluene, p-xylene, acetonitrile and chloroform were all purchased from Aldrich and used without further purification. Oleylamine, 70% technical grade, was purchased from Fluka and filtered through a 0.45 μm filter (Whatman GE). Elvacite® 2028 and Elvacite® 2008 were obtained from Lucite International, Inc. (Cordova, Tenn.).

### General Procedure for the Preparation of Solar Cells

Mo-Sputtered Substrates. Substrates for solar cells were prepared by coating a soda lime glass substrate with a 500 nm layer of patterned molybdenum using a Denton Sputtering System. Deposition conditions were: 150 watts of DC Power, 20 sccm Ar, and 5 mT pressure.

### Cadmium Sulfide Deposition.

Precursor solutions for the CdS bath were prepared according to Table 1, and were combined at room temperature in the reaction vessel which contained prepared substrates, such that substrates to be coated would be fully submerged. Immediately after mixing of the precursor solutions, the vessel containing the mixed components was placed in a water-heated vessel (65° C.) (large crystallization dish). CdS was deposited on the sample for 17.5 minutes. Samples were rinsed in DI water for an hour, and dried at 200° C. for 15 minutes.

TABLE 1
Precursor solutions for CdS bath.

| | | Concentration | | |
|---|---|---|---|---|
| | FW (g/mol) | (mol/L) | Volume (mL) | Amount (g) |
| Water | 18 | | 183 | 183 |
| NH4OH | NA | 28% | 32.6 | |
| CdSO4 | 208.46 | 0.015 | 25 | 0.0781725 |
| Thiourea | 76.12 | 1.5 | 12.5 | 1.42725 |
| | | Total volume = | 253.1 | |

### Transparent Conductor Deposition.

A transparent conductor was sputtered on top of the CdS with the following structure: 50 nm of insulating ZnO (150 W RF, 5 mTorr, 20 sccm) and 500 nm of Al-doped ZnO using a 2% Al₂O₃, 98% ZnO target (75 W RF, 10 mTorr, 20 sccm).

### Example 1

### Synthesis of Copper Zinc Tin Sulfur Nanoparticles with Consecutive Addition of Precursors with 230° C. Reaction Temperature

In the following procedure, all metal salts and elemental sulfur were dissolved in oleylamine at 100° C.: A solution of 80 mg (0.586 mmol) of zinc chloride dissolved in 10 mL of oleylamine and a solution of 102 mg (0.587 mmol) of tin(II) chloride dissolved in 10 mL of oleylamine were mixed with stirring in a flask that was previously degassed and heated to 110° C. under an Ar atmosphere. After 5 minutes of stirring, a solution of 77 mg (0.777 mmol) of cuprous chloride dissolved in 10 mL of oleylamine was added to the reaction mixture, and the resulting solution was stirred for an additional 5 minutes. At this point, a solution of 163 mg (5.08 mmol) of sulfur dissolved in 10 mL of oleylamine was added to the system, and the reaction temperature was raised to 230° C. at a rate of 10° C./min.

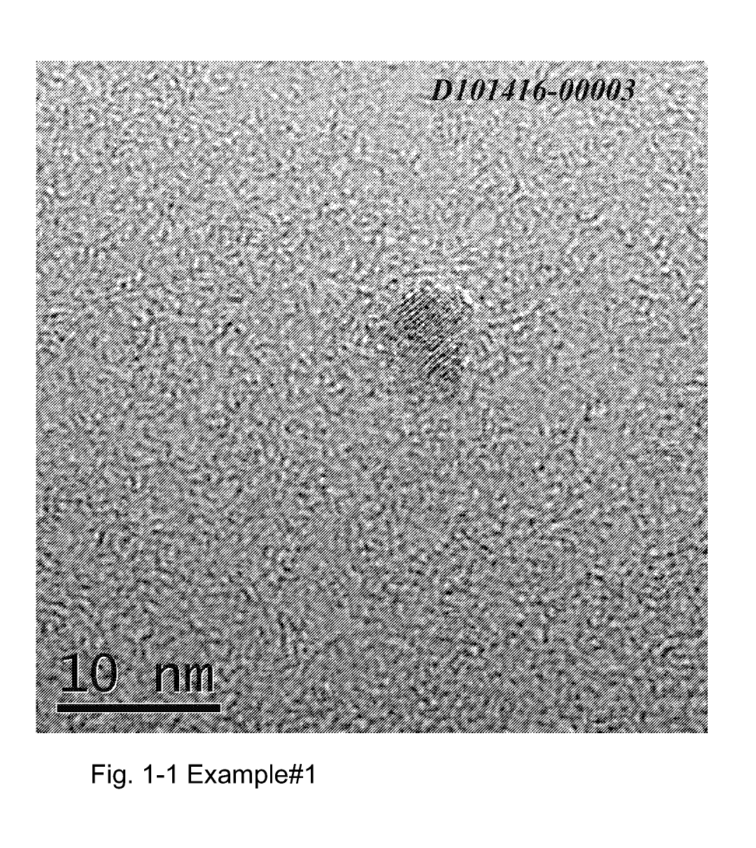

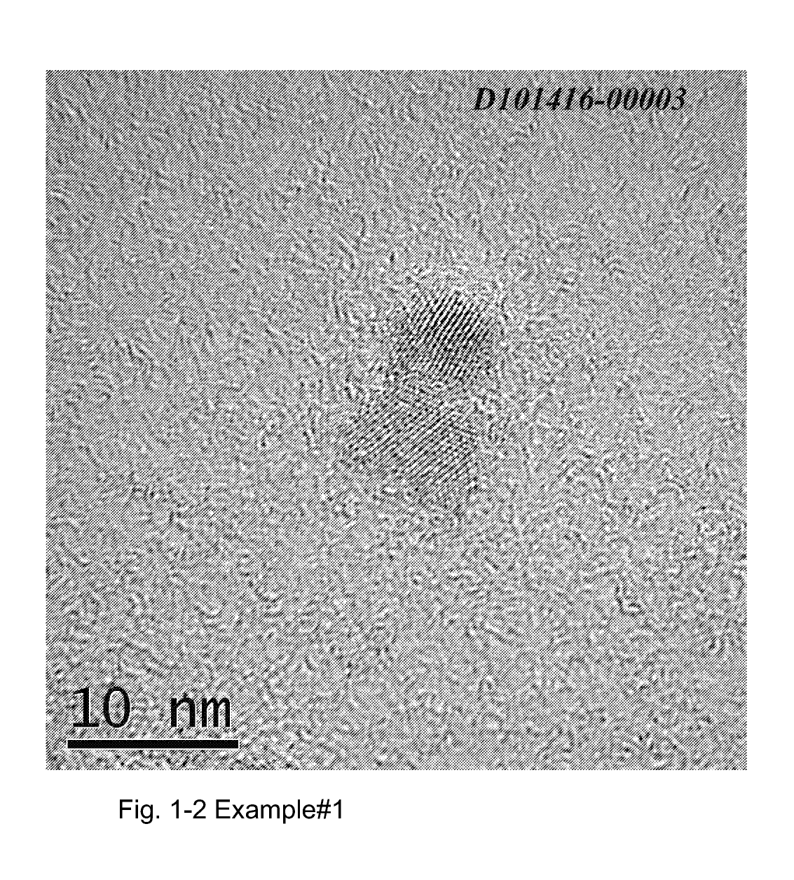

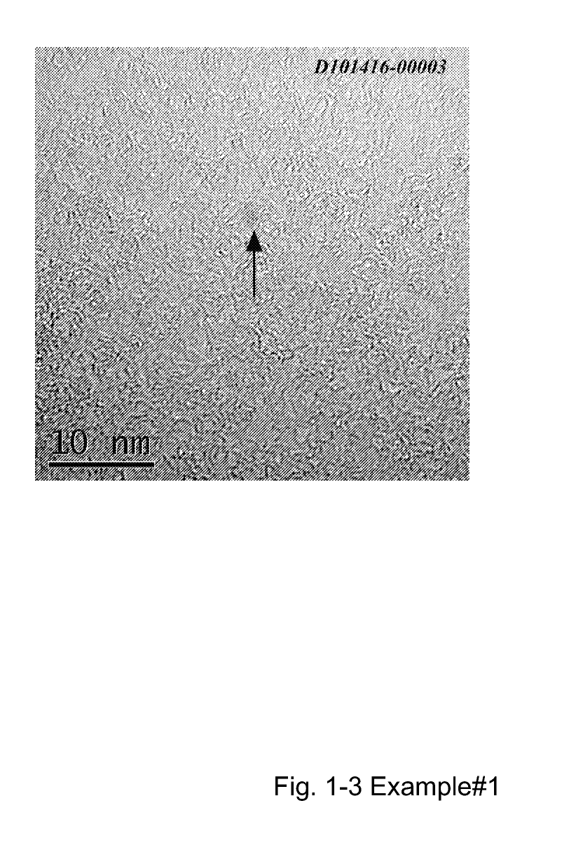

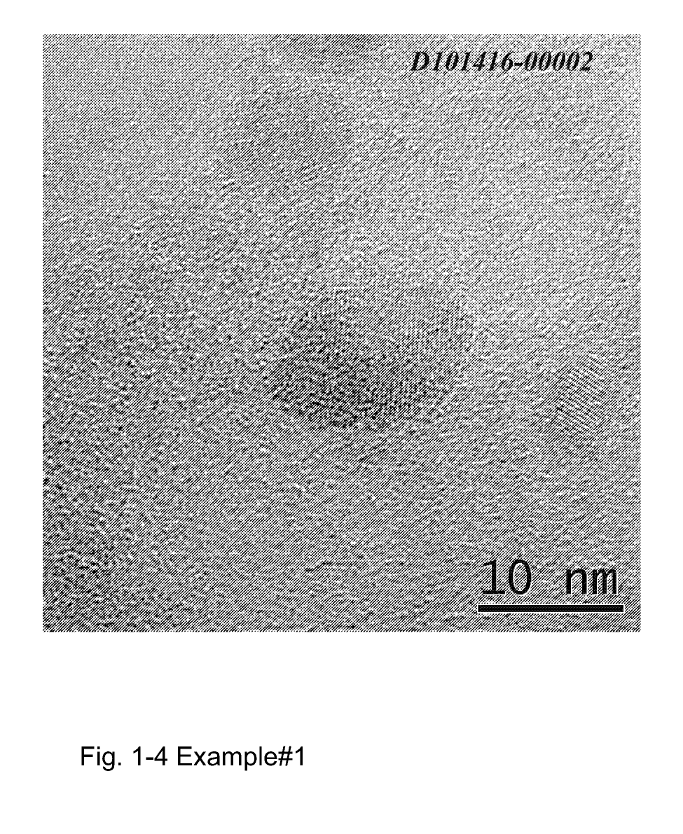

After reaching 230° C., the system was maintained at this temperature for 10 minutes and then the heating was turned off. The reaction was allowed to cool down naturally with stirring with the heating block remaining in place as it cooled. Following cooling, 80 mL of ethanol was added to the reaction mixture. The particles were collected via centrifugation and decanting of the solvent. The presence of kesterite structure was determined by XRD and the ratio of Cu:Zn:Sn:S was determined via ICP (see Table 2). The particle size was determined using DLS, TEM (see FIGS. 1-1, 1-2, 1-3, 1-4) and AFM. The particle size ranged between 1-10 nm.

### Example 2

### Synthesis of Copper Zinc Tin Sulfur Nanoparticles with Consecutive Addition of Precursors with 160° C. Reaction Temperature

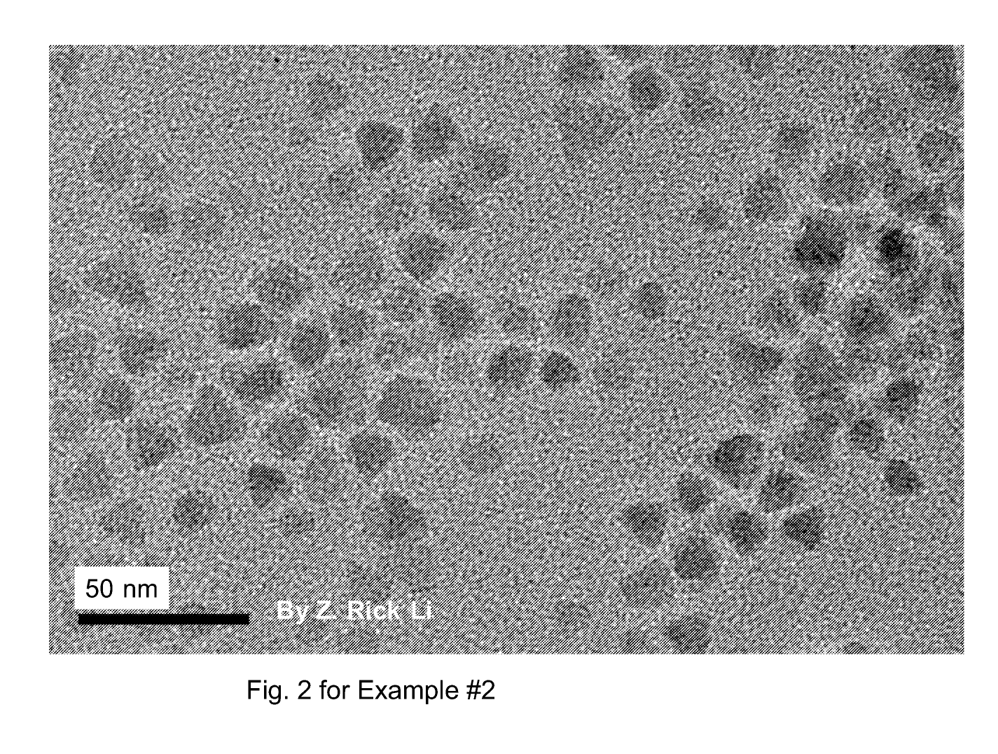

In the following procedure, all metal salts and elemental sulfur were dissolved in oleylamine at 100° C.: A solution of 80 mg (0.586 mmol) of zinc chloride dissolved in 10 mL of oleylamine and a solution of 102 mg (0.587 mmol) of tin(II) chloride dissolved in 10 mL of oleylamine were mixed with stirring in a flask that was previously degassed and heated to 160° C. under an Ar atmosphere. After 5 min of stirring, a solution of 77 mg (0.777 mmol) of cuprous chloride dissolved in 10 mL of oleylamine was added and the three components were stirred for an additional 5 minutes. At this point, a solution of 163 mg (5.08 mmol) of elemental sulfur dissolved in 10 mL of oleylamine was added to the system while the reaction temperature was maintained at 160° C. for an additional 10 minutes. The heating was then turned off and the reaction was allowed to cool down naturally under stirring with the heating block remaining it place as it cooled down. Upon cooling, 40 mL of a 1:1 mixture of hexane and ethanol was added to the reaction mixture. The particles were collected via centrifugation and decanting of the solvent. The presence of kesterite structure was determined by XRD and the ratio of Cu:Zn:Sn:S was determined via EDX (see Table 2). The particle size was determined using DLS, TEM (FIG. 2) and AFM. The particle sizes ranged from 10-50 nm.

### Example 3

### Synthesis of Copper Zinc Tin Selenium Nanoparticles with Consecutive Addition of Precursors

In the following procedure, all metal salts and elemental selenium were dissolved in oleylamine at 100° C.: The procedure of Example 1 was followed with elemental selenium 401 mg (5.08 mmol) replacing elemental sulfur. The presence of kesterite structure was determined by XRD.

### Example 4

### Synthesis of Copper Zinc Tin Sulfur Nanoparticles with Simultaneous Addition of Precursors

In the following procedure, all metal salts and elemental sulfur were dissolved in oleylamine at 100° C.: A solution of 80 mg (0.586 mmol) of zinc chloride dissolved in 10 mL of oleylamine, a solution of 102 mg (0.587 mmol) of tin(II) chloride dissolved in 10 mL of oleylamine, a solution of 77 mg (0.777 mmol) of cuprous chloride dissolved in 10 mL of oleylamine, and a solution of 163 mg (5.08 mmol) of elemental sulfur dissolved in 10 mL of oleylamine were mixed simultaneously, and the reaction temperature was raised to 230° C. at a rate of 10° C./min. After reaching 230° C., the system was maintained at this temperature for 10 minutes and then the heating was turned off. The reaction was allowed to cool down naturally with stirring with the heating block remaining in place as it cooled down. Following cooling, 80 mL of ethanol was added to the mixture. The particles were collected via centrifugation and decanting of the solvent. The particle sizes ranged from 10-50 nm and the composition indicated a ratio of 1:2 of Zn:Sn within CZTS. The presence of kesterite structure was determined by XRD and the ratio of Cu:Zn:Sn:S was determined via EDX (see Table 2). The particle size was determined using DLS, TEM and AFM. While maintaining a similar XRD pattern, a different composition was obtained.

### Comparative Example 5

### Nanoparticle Synthesis Using Thiourea as the Sulfur Source

A mixture of 0.1 g of cuprous chloride (1 mmol of Cu), 0.068 g of zinc chloride (0.5 mmol of Zn), 0.094 g of tin(II) chloride (0.5 mmol of Sn), and 10 mL of oleylamine is vigorously stirred and degassed in a Schlenk flask for 30 minutes at 60° C. by pulling vacuum with the Schlenk line. The mixture is then heated to 130° C. under nitrogen for 10 minutes. During heating, the solution turns from blue to yellow, indicating the formation of oleylamine complexes of Cu, Zn and Sn. Meanwhile, a thiourea solution is prepared by dissolving 0.076 g of thiourea (1.0 mmol) in 1 mL of oleylamine at 200° C. under nitrogen in a Schlenk flask. The Zn/Sn/Cu/oleylamine reactant solution is cooled to 100° C. and the thiourea reactant solution is added via cannula. Immediately after injection, the reaction mixture is heated to 240° C. at a rate of 15° C./min. After 1 hour, the Schlenk flask containing the nanocrystals is removed from the heating mantle and allowed to cool to room temperature. Ethanol (30 mL) is then added to precipitate the nanocrystals, followed by centrifugation at 7000 rpm for 3 minutes. The supernatant is decanted off of the nanocrystals and discarded. The nanocrystals redisperse in a variety of non-polar organic solvents, including chloroform, hexane, and toluene. Prior to characterization, dispersions are typically centrifuged again at 7000 rpm for 5 min to remove inadequately capped nanocrystals. The sample was characterized via XRD and EDAX (see Table 2). The XRD results reveal the presence of SnS, ZnS, Cu2S. The small amount of Zn detected by EDAX reflects that this process, which is used to synthesize other type of chalcogenide-containing materials, cannot be extrapolated for CZTS synthesis.

TABLE 2
Cu, Zn, Sn and S Stoichiometry for Examples 1 and 2 with Consecutive
Addition of Precursors and Examples 4 (Simultaneous Addition of
Precursors) and Comparative Example 5 (Thiourea Precursor)

| Example | Method | Cu | Zn | Sn | S |
|---|---|---|---|---|---|
| 1 | ICP | 1.87 | 1.50 | 1.14 | 4.00 |
| 2 | EDAX | 1.96 | 1.56 | 1.19 | 4.18 |
| 4 | EDAX | 2.26 | 0.63 | 1.30 | 4.00 |
| 5 | EDAX | 2.00 | 0.10 | 4.02 | 1.54 |

### Example 6

### Preparation of CZTS Ink in Toluene

An ink was prepared by redispersing 0.086 g of CZTS nanoparticles produced by the procedure of Example 1. The particles were dispersed via ultrasonication in 1 mL of toluene (density 0.8669 g/mL) to generate an ink with a nanoparticle concentration of 10 wt %.

### Example 7

### Preparation of CZTS Ink in p-Xylene with Elvacite® 2028 Binder

An ink was prepared by the following steps: First, 0.172 g of CZTS nanoparticles prepared by the procedure of Example 1 were dispersed via ultrasonication in 1 mL of p-xylene (density 0.861 g/mL) to generate a 20 wt % suspension of nanoparticles. Then, the nanoparticle suspension was mixed with 1 mL of a solution of 2 wt % of Elvacite 2028 p-xylene to generate an ink with 10% wt concentration of nanoparticles.

### Example 8

### Preparation of CZTS Ink in Toluene with Elvacite® 2028 Binder

An ink was prepared by the following steps: First, 0.172 g of CZTS nanoparticles prepared by the procedure of Example 1 were dispersed via ultrasonication in 1 mL of toluene (density 0.861 g/mL) to generate a 20 wt % suspension of nanoparticles. Then, the nanoparticle suspension was mixed with 1 mL of a solution of 2 wt % Elvacite® 2028 in toluene to generate an ink with 10 wt % concentration of nanoparticles.

### Example 9

### Preparation of CZTS Ink in Acetonitrile with Elvacite® 2008 Binder

An ink was prepared by the following steps: First, 0.172 g of CZTS nanoparticles prepared by the procedure of Example 1 were dispersed via ultrasonication in 1 mL of acetonitrile (density 0.786 g/mL) to generate a 20 wt % suspension of nanoparticles. Then, the nanoparticle suspension was mixed with 1 mL of a solution of 2 wt % Elvacite® 2008 in acetonitrile to generate an ink with 10 wt % concentration of nanoparticles.

### Example 10

### CZTS Nanoparticle Synthesis: Exchange of Oleylamine with Butylamine

CZTS nanoparticles were prepared according to the procedure of Example 1, redispersed in toluene, centrifuged and then the solvent was decanted. The pellet was dried under vacuum. The dry material was then weighed and 0.3 g of material was then placed in a round bottom flask equipped with stirring bar under an Ar atmosphere. Anhydrous butyl amine (5 mL) was added to the flask using a syringe, and the reaction was allowed to stir for 3 days at room temperature to give an ink in butylamine. Next, the particles were precipitated by adding 15 mL of ethanol and collected via centrifugation and decanting of solvent to give a pellet of nanoparticles.

### Example 11

### Preparation of Butylamine-Capped CZTS-Nanoparticle Ink in Chloroform

The nanoparticle pellet prepared according to Example 10 is redispersed in chloroform at a concentration of 150 mg/mL and is then filtered through a 0.22 ium polytetrafluoroethylene filter to generate an ink

### Example 12

### Formation of CZTS Film

Wet pellets of CZTS (˜100 mg) prepared according to Example 1 were dissolved in 0.5 mL of toluene, yielding fluid suspensions. The suspensions were sonicated 5 to 60 minutes using a Branson 25-10 Sonicator, in steps of 5 minutes. The highest quality dispersions were obtained with sonication times between 30 and 45 minutes.

Using a Speed-line Technologies 3GP benchtop spin-coater, samples were then spin-coated onto glass substrates and also onto the molybdenum-coated side of glass substrates patterned with sputtered molybdenum. Coating speeds ranged from 500-1500 rpms and coating times ranged from 10 to 30 seconds. The highest quality coatings were obtained for 1000-rpm, 20-sec spinning conditions. The resulting films varied in thickness between 50 and 800 nm.

Films were then annealed in either a furnace or a rapid thermal annealing processor. Annealing temperatures ranged from 400 to 550° C., and times varied from 10-30 minutes. The highest quality annealed films were obtained by annealing for 15 minutes at temperatures between 500 and 550° C. Film thickness and roughness were obtained with a profilometer and films were further characterized by optical spectra. For Rappid thermal annealing, a MILA-5000 Infrared Lamp Heating System by ULVAC-RICO Inc. (Methuen, Mass.) was utilized for heating and the system was cooled using a Polyscience (Niles, Ill.) recirculating bath held at 15° C. Samples were heated under nitrogen purge as follows: 20 for 10 min, ramp to 400° C. in 1 min; hold at 400° C. for 2 min; cool back to 20° C. during ˜30 min.

### Example 13

### Densification of CZTS Films through Soaking with Ethanol

Pre-annealed films were prepared as described in Example 12. These films were left on the spin coater after being coated and were then soaked with ethanol. After a few seconds of soaking, the spinning program was re-run to aid drying of the film. The resulting films were denser and harder than the pre-soaked films.

### Example 14

### Formation of Bar-Coated CZTS Films

Wet pellets of CZTS (˜100 mg) prepared according to Example 1 were dissolved in ˜0.5 mL of various solvents, including toluene and chloroform to give inks The resulting CZTS inks were bar-coated onto glass substrates. Two of the bar-coated films were annealed in a furnace at 550° C. for 15 minutes. The films were characterized via XRD and some of films were scrapped and analyzed via HR-TEM.

### Example 15

### Solar Cell with Spin-Coated CZTS Nanoparticle-Derived Absorber Layer

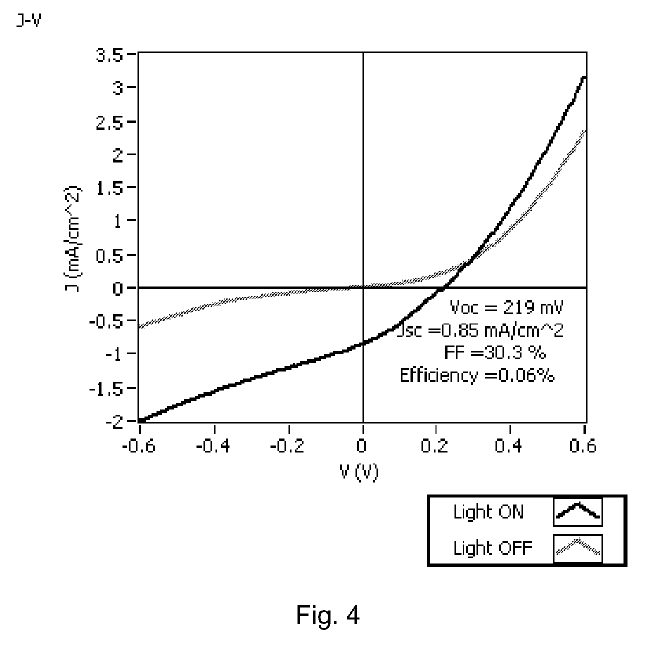

An annealed film of p-type CZTS absorber on Mo-sputtered soda lime glass was prepared as described in Example 12. The sample was then placed in a CdS bath and about 50 nm of n-type CdS was deposited on top of the CZTS film. The transparent conductor was then sputtered on top of the CdS. The finished device was tested under 1 sun illumination and the J-V characteristics are illustrated in FIG. 4

### Example 16

### CZTS-Based Solar Cell on Polyimide Substrate with Thermally Evaporated Sodium Layer

A solar cell is fabricated with a CZTS absorber layer using high-temperature polyimide film as the substrate. The procedure of Example 15 is followed with the modification that in order to provide some of the sodium necessary for high performance solar cells, a very thin layer of Na (less than 1 nm) is thermally evaporated on the Mo. The CZTS ink is then coated onto the polyimide/Mo/Na substrate.

### Example 17

### Solar Cell on Polyimide Substrate Fabricated from Sodium-Doped CZTS Ink

A solar cell is fabricated with a CZTS absorber layer using high-temperature polyimide film as the substrate according to the procedure of Examples 15. Sodium octanoate is incorporated into the ink at 0.5 wt %.

### Example 18

### CZTS Ink Doped with Elemental Chalcogen

An ink of CZTS nanoparticles is formed according to the procedure of Example 6. Submicron-sized elemental sulfur particles are added to the ink at 1 wt % with sonication. A solar cell is fabricated with this ink by following the procedure of Example 15.

### Example 19

### CZTS Ink Doped with Binary Chalcogenide Particles

An ink of CZTS nanoparticles is formed according to the procedure of Example 6. Binary chalcogenide nanoparticles of SnS₂ and ZnS are added to the ink at 0.2 wt % each with sonication. Utilizing this ink, a coating and solar cell are fabricated according to the procedure of Example 15.

### Examples 20-25

### Coatings and Solar Cells Based on a Variety of CZTS Inks

Inks of CZTS nanoparticles are formed according to the procedures listed in Table 3. Utilizing these inks, coatings and solar cells are fabricated according to the procedure of Example 15.

TABLE 3
Inks utilized in solar cells in Examples 20-25.

| | Ink Prepared According to the Procedure of the Following |
|---|---|
| Example | Examples: |
| 20 | Example 2 |
| 21 | Example 3 |
| 22 | Example7 |
| 23 | Example 8 |
| 24 | Example 9 |
| 25 | Example 11 |

### Example 26

### Variation in CZTS Composition: Sulfur Gradient

Ten inks of CZTS nanoparticles doped with elemental sulfur are formed according to the procedure of Example 18 with the weight percent sulfur in the inks varying from 1.0 to 0.1 wt % with steps of 0.1 wt %. A CZTS film with a sulfur gradient is created on Mo-sputtered soda lime glass by spray-coating the CZTS inks in consecutive spray passes using the ink compositions for each layer as shown in Table 4. Utilizing this absorber layer, a solar cell is fabricated according to the procedure of Example 15.

### Example 27

### Variation in CZTS Composition: Cu-Poor with Cu Gradient

Ten inks of CZTS nanoparticles doped with binary chalcogenide nanoparticles of SnS₂ and ZnS are formed according to the procedure of Example 19 with the weight percent of binary chalcogenide nanoparticles in the inks varying from 0 to 0.45 wt % with steps of 0.05 wt %. A copper-poor CZTS film with a copper gradient is created on Mo-sputtered soda lime glass by spray-coating the CZTS inks in consecutive spray passes using the ink compositions for each layer as shown in Table 4. Utilizing this absorber layer, a solar cell is fabricated according to the procedure of Example 15.

TABLE 4
Wt % of dopants in CZTS inks used in layers of gradient films

| | Wt % Additive in Ink Used for Layers 1-10 (L1-L10) | | | | | | | | | |
|---|---|---|---|---|---|---|---|---|---|---|
| Ex | L1 | L2 | L3 | L4 | L5 | L6 | L7 | L8 | L9 | L10 |
| 26 | 1.0 | 0.9 | 0.8 | 0.7 | 0.6 | 0.5 | 0.4 | 0.3 | 0.2 | 0.1 |
| 27 | 0 | 0.05 | 0.1 | 0.15 | 0.2 | 0.25 | 0.3 | 0.35 | 0.4 | 0.45 |

### Example 28

### Spray-Coating of CZTS Nanoparticles

CZTS nanoparticles (100 mg) were prepared according to the procedure of Example 1. The nanoparticles were suspended in 5 mL of chloroform and the suspension then sonicated for 10 minutes prior to deposition. The ink is sprayed on Mo-sputtered soda lime glass according to the conditions given in Table 5. Utilizing this absorber layer, solar cells are fabricated according to the procedure of Example 15.

### Example 29

### Insulating ZnO Window

A solar cell is fabricated according to the procedure of Example 15 utilizing insulating ZnO as the window in place of CdS.

### Example 30

### Solar Cell with CZTS Absorber Layer and Carbon Nanotube-Based Transparent Conductor

A solar cell is fabricated according to the procedure of Example 15 utilizing utilizing a carbon nanotube-based transparent conductor in place of ZnO:Al.

### Example 31

### CZTS Nanoparticles Synthesized Via Microwave Radiation

In the following procedure, all metal salts and elemental sulfur are dissolved in oleylamine at 100° C.: A solution of 80 mg (0.586 mmol) of zinc chloride dissolved in 5 mL of oleylamine, a solution of 102 mg (0.587 mmol) of tin(II) chloride dissolved in 5 mL of oleylamine, a solution of 77 mg (0.777 mmol) of cuprous chloride dissolved in 5 mL of oleylamine and a solution of 163 mg (5.08 mmol) of elemental sulfur dissolved in 5 mL of oleylamine were mixed simultaneously and loaded in a microwave synthesizer special vial equipped with stir bar. The vial is then loaded into an Initiator-8 microwave (Biotage, Sweden) system with a heat set point of 230° C. After reaching 230° C., the system was maintained at this temperature for 10 minutes and then the vial is removed from the system. Following cooling down in the rack for 30 min, the vial is opened and the reaction mixture is transferred as equal volumes (20 mL each) into two 50 mL Falcon test tubes. Next, a volume of 20 mL of ethanol is added to each tube. The particles are collected via centrifugation and decanting of the solvent.

### Example 32

### Sulfurization of CZTS Films

CZTS nanoparticles were prepared according to the procedure of Example 1. Wet pellets of CZTS (˜100 mg) prepared according to Example 1 were suspended in ˜0.5 mL of various solvents, including toluene and chloroform to give inks The resulting CZTS inks were bar-coated onto glass substrates. Bar-coated films were annealed in a furnace at 500° C. for 1 hour under rich sulfur atmosphere and under continuous flow of nitrogen atmosphere. Annealings were carried out in a single-zone Lindberg/Blue (Ashville, N.C.) tube furnace equipped with an external temperature controller and a two-inch quartz tube. The coated substrates were placed on quartz plates inside of the tube. A 3-inch long ceramic boat was loaded with 2.5 g of elemental sulfur and placed near the nitrogen inlet, outside of the direct heating zone.

### Example 33

### Selenization of CZTS Films

CZTS nanoparticles are prepared according to the procedure of Example 1. Wet pellets of CZTS (˜100 mg) prepared according to Example 1 are suspended in ˜0.5 mL of various solvents, including toluene and chloroform to give inks The resulting CZTS inks are bar-coated onto glass substrates. Bar-coated films are annealed in a furnace at 500° C. for 1 hour under rich selenium atmosphere and under continuous flow of nitrogen atmosphere. The samples are placed in a 5″ L×1.4″ W by 1″ H graphite box with ⅛″ walls that is equipped with a lid with a lip and a 1 mm hole in the center (custom-made by Industrial Graphite Sales, Harvard, Ill.). Each graphite box is equipped with two small ceramic boats (0.984″ L×0.591″ W×0.197″ H) at each end, containing 0.1 g of selenium. The graphite box is then place in a two-inch tube, with up to two graphite boxes per tube. Vacuum is applied to the tube for 10-15 min, followed by a nitrogen purge for 10-15 min. This purging process is carried out three times. The tube containing the graphite boxes is then heated for 1 hour at 500° C. in the single-zone furnace with both heating and cooling carried out under a nitrogen purge. The exiting gas is sparged through consecutive bubblers: 1 M NaOH (aq) followed by 1 M Cu(NO3)2 (aq).

Where a range of numerical values is recited or established herein, the range includes the endpoints thereof and all the individual integers and fractions within the range, and also includes each of the narrower ranges therein formed by all the various possible combinations of those endpoints and internal integers and fractions to form subgroups of the larger group of values within the stated range to the same extent as if each of those narrower ranges was explicitly recited. Where a range of numerical values is stated herein as being greater than a stated value, the range is nevertheless finite and is bounded on its upper end by a value that is operable within the context of the invention as described herein. Where a range of numerical values is stated herein as being less than a stated value, the range is nevertheless bounded on its lower end by a non-zero value.

In this specification, unless explicitly stated otherwise or indicated to the contrary by the context of usage, amounts, sizes, ranges, formulations, parameters, and other quantities and characteristics recited herein, particularly when modified by the term “about”, may but need not be exact, and may also be approximate and/or larger or smaller (as desired) than stated, reflecting tolerances, conversion factors, rounding off, measurement error and the like, as well as the inclusion within a stated value of those values outside it that have, within the context of this invention, functional and/or operable equivalence to the stated value.

In this specification, unless explicitly stated otherwise or indicated to the contrary by the context of usage, where an embodiment of the subject matter hereof is stated or described as comprising, including, containing, having, being composed of or being constituted by or of certain features or elements, one or more features or elements in addition to those explicitly stated or described may be present in the embodiment. An alternative embodiment of the subject matter hereof, however, may be stated or described as consisting essentially of certain features or elements, in which embodiment features or elements that would materially alter the principle of operation or the distinguishing characteristics of the embodiment are not present therein. A further alternative embodiment of the subject matter hereof may be stated or described as consisting of certain features or elements, in which embodiment, or in insubstantial variations thereof, only the features or elements specifically stated or described are present.

What is claimed is:

1. A quaternary nanoparticle comprising copper, zinc, tin, a chalcogen, and a capping agent, wherein the chalcogen is selected from the group consisting of sulfur, selenium and mixtures thereof.

2. A nanoparticle according to claim 1 that has a longest dimension of about 1 nm to about 1000 nm, and/or a kesterite structure.

3. A nanoparticle according to claim 1 wherein the molar ratio of copper to zinc to tin to chalcogen is about 2:1:1:4; or the molar ratio of copper to zinc plus tin is less than one; or the molar ratio of zinc to tin is greater than one.

4. A nanoparticle according to claim 1 wherein the capping agent comprises (a) an organic molecule that comprises a nitrogen-, oxygen-, sulfur-, or phosphorus-based functional group; (b) a Lewis base; or (c) an electron pair-donor group, or a group that can be converted into an electron pair-donor group, that has a boiling point of less than about 150° C. at ambient pressure.

5. A composition comprising a plurality of nanoparticles according to claim 1, wherein the composition has a particle size distribution such that the average longest particle dimension is in the range of about 10 nm to about 100 nm with a standard deviation of about 10 nm or less.

6. A process for preparing a copper-zinc-tin-chalcogenide quaternary nanoparticle, comprising (a) forming in a solvent a reaction mixture of (i) metal salts and/or complexes of copper, zinc and tin, (ii) one or more chalcogen precursor(s), and (iii) a first capping agent, and (b) heating the reaction mixture to form a nanoparticle.

7. A process according to claim 6 wherein individual metal salts and/or complexes of copper, zinc and tin are separately added in sequence to a mixture of a solvent and the first capping agent to form a reaction mixture, followed by the addition to the reaction mixture of a chalogen precursor.

8. A process according to claim 6 comprising (a) contacting the reaction mixture with a second capping agent that has greater volatility than the first capping agent to exchange in the nanoparticle the second capping agent for the first capping agent; or (b) recovering the nanoparticle from the reaction mixture followed by contacting the nanoparticle with a second capping agent that has greater volatility than the first capping agent to exchange in the nanoparticle the second capping agent for the first capping agent.

9. A process according to claim 8 wherein the second capping agent has a boiling point of less than about 200° C. at ambient pressure.

10. An ink comprising an organic solvent and a composition comprised of a plurality of nanoparticles according to claim 1.

11. An ink according to claim 10 further comprising one or more binders or surfactants selected from the group consisting of decomposable binders, decomposable surfactants, cleavable surfactants, surfactants with a boiling point less than about 250° C., and mixtures thereof.

12. A composition comprising a plurality of nanoparticles according to claim 1 fabricated as a film.

13. A method of forming a film comprising depositing on a substrate a layer of a composition that comprises a plurality of nanoparticles according to claim 1, and drying the deposited layer of composition to remove solvent therefrom.

14. A method according to claim 13 further comprising heating the film in an atmosphere to anneal it; wherein the atmosphere is inert, or comprises a reactive component selected from the group consisting of selenium vapor, sulfur vapor, hydrogen, hydrogen sulfide, hydrogen selenide, and mixtures thereof.

15. A method according to claim 13 wherein the film comprises a first capping agent, and the method further comprises contacting the film with a second capping agent that has greater volatility than the first capping agent to exchange in the nanoparticles of the film the second capping agent for the first capping agent.

16. A method according to claim 15 wherein the second capping agent has a boiling point of less than about 200° C. at ambient pressure.

17. An electronic device comprising a film that comprises a plurality of nanoparticles according to claim 1.

18. A device according to claim 17 wherein the film comprises multiple layers; and a first layer comprises a plurality of nanoparticles according to claim 1, and a second layer comprises a binary semiconductor, a chalcogen source, a sodium-containing material, or a mixtures thereof.

19. A device according to claim 18 wherein a chalcogen source is selected from the group consisting of chalcogen particles, binary chalcogenide particles, and mixtures thereof; and/or a sodium-containing material is selected from the group consisting of sodium salts of deprotonated alcohols, sodium salts of deprotonated acids, sodium hydroxide, sodium acetate, sodium sulfide, and mixtures thereof.

20. A device according to claim 18 wherein the first layer is adjacent to the second layer.
